(19) United States
(12) Patent Application Publication
(10) Pub. No.: US 2025/0054790 A1
(43) Pub. Date: Feb. 13, 2025

(54) MAPPING APPARATUS AND LOAD PORT APPARATUS

(71) Applicant: TDK Corporation, Tokyo (JP)

(72) Inventors: Tatsuhiro KOTSUGAI, Tokyo (JP); Jo SUGAWARA, Tokyo (JP); Tomoshi ABE, Tokyo (JP)

(73) Assignee: TDK Corporation, Tokyo (JP)

(21) Appl. No.: 18/798,050

(22) Filed: Aug. 8, 2024

(30) Foreign Application Priority Data
Aug. 10, 2023 (JP) 2023-131076

(51) Int. Cl. H01L 21/67; H01L 21/677; H01L 21/687

(52) U.S. Cl. CPC H01L 21/67271; H01L 21/67259; H01L 21/67772; H01L 21/68792

(57) ABSTRACT

A mapping apparatus includes a mapping frame configured to move in the first direction and a second direction; a first detecting unit including a pair of first protrusions protruding from the mapping frame in the second direction in an amount of a first length, the first protrusions being disposed with a first distance therebetween in a third direction, and first sensors near respective extremities of the first protrusions; and a second detecting unit including a pair of second protrusions protruding from the mapping frame in an amount of a second length longer than the first length, the second protrusions being disposed at locations same as those of the first protrusions in the third direction, and second sensors near respective extremities of the second protrusions, the second detecting unit being disposed at a location different from that of the first detecting unit by a predetermined distance.

### BACKGROUND OF THE INVENTION

The present disclosure relates to a mapping apparatus and a load port apparatus.

### BACKGROUND

An apparatus (e.g., a load port apparatus) that delivers plate-like objects (e.g., substrates) is provided with a mapping apparatus that detects storing conditions of the objects stored in a container. The mapping apparatus detects the number of the objects in the container, their locations, and also whether the objects are correctly stored in the container (see Patent Document 1). The objects detectable by the mapping apparatus include, other than silicon substrates and those that have been fabricated, sheet-like materials (e.g., glass substrates).

Meanwhile, as objects transported in a semiconductor fabrication plant have larger sizes and smaller thicknesses, containers and the objects stored in the containers have diversified. For example, containers storing 200 mm (8-inch) silicon wafers and containers storing 300 mm (12-inch) silicon wafers go through processes in the semiconductor fabrication plant at the same time; and the two types of containers may be transported to a predetermined load port apparatus one after another. In this situation, a mapping apparatus provided for the load port apparatus demands support for both the 200 mm silicon wafers and the 300 mm silicon wafers.

However, if an attempt is made to apply a conventional mapping apparatus that supports the containers storing the 200 mm silicon wafers to the containers storing the 300 mm silicon wafers, a detecting unit of the mapping apparatus and the 300 mm silicon wafers slightly protruding from the containers, if any, may collide, even if the protruding amount is within tolerance for the 200 mm silicon wafers. This is because, in a situation where the conventional mapping apparatus that supports the containers storing the 200 mm silicon wafers is applied to the containers storing the 300 mm silicon wafers, acceptable tolerance for the protrusion of the silicon wafers is reduced.

### PRIOR ARTS

### Patent Document

Patent Document 1: JP Patent Application Laid Open No. 2011-35384

### BRIEF SUMMARY OF THE INVENTION

### Problem to be Solved by the Invention

The present disclosure relates to a mapping apparatus and a load port apparatus capable of preventing a collision between objects and sensors even if the objects have different sizes. Means for Solving the Problem

To achieve the above object, a mapping apparatus according to a first aspect of the present disclosure is
a mapping apparatus for detecting a storing condition of objects in a container capable of storing the objects at predetermined intervals along a first direction, including:
a mapping frame configured to move in the first direction and a second direction substantially perpendicular to the first direction;
a first detecting unit including
   a pair of first protrusions protruding from the mapping frame in the second direction in an amount of a first length, the first protrusions being disposed with a first distance therebetween in a third direction substantially perpendicular to
   the first direction and the second direction, and
   first sensors near respective extremities of the first protrusions; and
a second detecting unit including
   a pair of second protrusions protruding from the mapping frame in the second direction in an amount of a second length longer than the first length, the second protrusions being disposed at locations same as those of the first protrusions in the third direction, and
   second sensors near respective extremities of the second protrusions, the second detecting unit being disposed at a location different from that of the first detecting unit by a predetermined distance in the first direction.

The mapping apparatus according to the first aspect of the present disclosure includes the first detecting unit and the second detecting unit, which are disposed at the locations different by the predetermined distance in the first direction, which is the direction in which the objects overlap; and the protruding length (second length) of the second protrusions is longer than the protruding length (first length) of the first protrusions. Because the protruding length of the first detecting unit is short, it can detect the objects, which may collide with the second detecting unit having the longer protruding length, while avoiding contact with the objects protruding from the container; and appropriate operation of the mapping frame and the like can prevent a collision between the objects and the second detecting unit. By locating the first protrusions and the second protrusions at the same locations in the third direction, the second protrusions can have a large distance therebetween, making the most of an opening width of a container for objects having a smaller size; and the range of tolerance in the protruding amount of the objects can be widened.

For example, a mapping apparatus according to a second aspect of the present disclosure is a mapping apparatus for detecting a storing condition of objects in a container capable of storing the objects at predetermined intervals along a first direction, including:
a mapping frame movable in the first direction and a second direction substantially perpendicular to the first direction;
a first detecting unit including
   a pair of first protrusions protruding from the mapping frame in the second direction in an amount of a first length, the first protrusions being disposed with a first distance therebetween in a third direction substantially perpendicular to the first direction and the second direction, and
   first sensors near respective extremities of the first protrusions; and
a second detecting unit including
   a pair of second protrusions protruding from the mapping frame in the second direction in an amount of a second length longer than the first length, the second protrusions being disposed with a second distance narrower than the first distance therebetween in the third direction, and
   second sensors near respective extremities of the second protrusions,
the second detecting unit being disposed at a location different from that of the first detecting unit by a predetermined distance in the first direction.

Similarly to the mapping apparatus according to the first aspect, the mapping apparatus according to the second aspect of the present disclosure includes the first detecting unit and the second detecting unit, which are disposed at the locations different by the predetermined distance in the first direction, which is the direction in which the objects overlap; and the protruding length (second length) of the second protrusions is longer than the protruding length (first length) of the first protrusions. Because the protruding length of the first detecting unit is short, it can detect the objects, which may collide with the second detecting unit having the longer protruding length, while avoiding contact with the objects protruding from the container; and appropriate operation of the mapping frame and the like can prevent a collision between the objects and the second detecting unit. By making the second distance between the second protrusions narrower than the first distance between the first protrusions, avoided is overlapping of the first protrusions and a first direction upper surface of the container for the objects having a smaller size viewed from above. This enables the second protrusions to vertically pass through the level of the upper surface of the container to simplify movement of the mapping frame.

For example, either
the first direction may be a downward direction, and
the first detecting unit may be disposed at a level below the second detecting unit by the predetermined distance; or
the first direction may be an upward direction, and
the first detecting unit may be disposed at a level above the second detecting unit by the predetermined distance.

In the mapping apparatus according to the present disclosure, the first direction can be any direction. However, for example, a mapping apparatus whose first direction, which is the moving direction of the mapping frame at the time of detection, is a downward direction or an upward direction can be suitably used as the mapping apparatus according to the present disclosure.

The mapping apparatus according to the present disclosure may include, for example, a storage unit configured to store a result of detection of the objects by the second detecting unit.

The second detecting unit can detect whether the objects are correctly stored in the container as well as the number, locations, and the like of the objects stored in the container. For this reason, inclusion of the storage unit configured to store such a detection result enables an apparatus (e.g., a load port apparatus) to easily utilize, after the detection, the result of detection by the second detecting unit.

The mapping apparatus according to the present disclosure may include, for example, a movement control unit configured to stop movement of the mapping frame before the mapping frame is moved by the predetermined distance from a point of detection of the objects by the first sensors, provided that a first detection result is input to the movement control unit and indicates the detection of the objects by the first sensors, wherein the first detection result includes a result of detection of the objects by the first detecting unit.

Such a motion of the movement control unit can stop the movement of the mapping frame before the second detecting unit collides with the objects, even if a container for objects having a larger size contains objects having a large protruding amount. Note that, other than the movement control unit configured to stop the movement of the mapping frame, a movement control unit configured to slow the movement of the mapping frame down or to change the movement direction or method is conceivable.

The mapping apparatus according to the present disclosure may include, for example, a third detecting unit, wherein a shortest distance from a container central axis parallel to the first direction of the container to a detection location of the third detecting unit is longer than shortest distances from the container central axis to detection locations of the first detecting unit and the second detecting unit.

In such a mapping apparatus, the third detecting unit detects objects greatly protruding to the extent that they may collide with even the first detecting unit, if any, and controls movement of the mapping frame to enable prevention of a collision between the objects and the first and second detecting units.

A load port apparatus according to the present disclosure includes
any of the above mapping apparatuses;
an installation portion configured to have the container installed thereon; and
a door configured to open or close a lid of the container.

The mapping apparatus according to the present disclosure may be included in any apparatuses and can be suitably used as a part of an interface (e.g., a load port apparatus provided for a semiconductor fabrication apparatus or the like) of delivering substrates or the like using a container in a semiconductor plant.

### BRIEF DESCRIPTION OF THE SEVERAL VIEWS OF THE DRAWING

FIG. 1 is a schematic view of a load port apparatus including a mapping apparatus according to a first embodiment of the present disclosure.

FIG. 2 is an enlarged perspective view of a main part of the mapping apparatus included in the load port apparatus shown in FIG. 1.

FIG. 3 is a front elevational view of the main part of the mapping apparatus viewed along a direction opposite a second direction.

FIG. 4 is a plan view of the main part of the mapping apparatus viewed along a first direction.

FIG. 5 is a schematic view illustrative of shapes of a first protrusion and a second protrusion of the mapping apparatus.

FIG. 6 is a schematic view illustrative of a state in which the mapping apparatus detects objects with different sizes.

FIG. 7 is a diagram (partial sectional view) showing a first stage in a detection operation of the mapping apparatus shown in FIG. 1.

FIG. 8 is a diagram (partial sectional view) showing a second stage in the detection operation of the mapping apparatus shown in FIG. 1.

FIG. 9 is a diagram (partial sectional view) showing a third stage in the detection operation of the mapping apparatus shown in FIG. 1.

FIG. 10 is a schematic view comparing a mapping apparatus according to a comparative example and the mapping apparatus according to the first embodiment.

FIG. 11 is a schematic view comparing the mapping apparatus according to the first embodiment and a mapping apparatus according to a second embodiment.

FIG. 12 is a schematic perspective view of a main part of the mapping apparatus according to the second embodiment of the present disclosure viewed from diagonally above.

FIG. 13 is a schematic perspective view of the main part of the mapping apparatus according to the second embodiment of the present disclosure viewed from diagonally below.

FIG. 14 is a schematic view of detection axes of detecting units of the mapping apparatus according to the second embodiment.

### DETAILED DESCRIPTION OF THE INVENTION

### First Embodiment

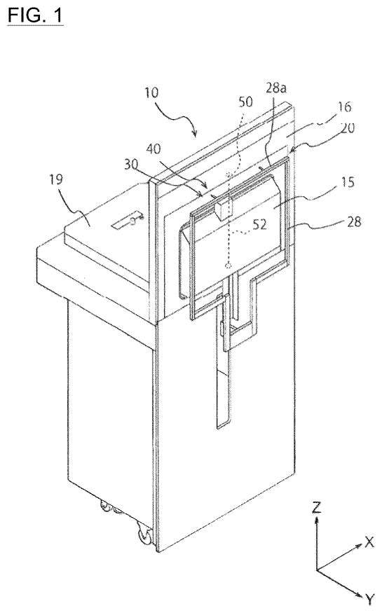

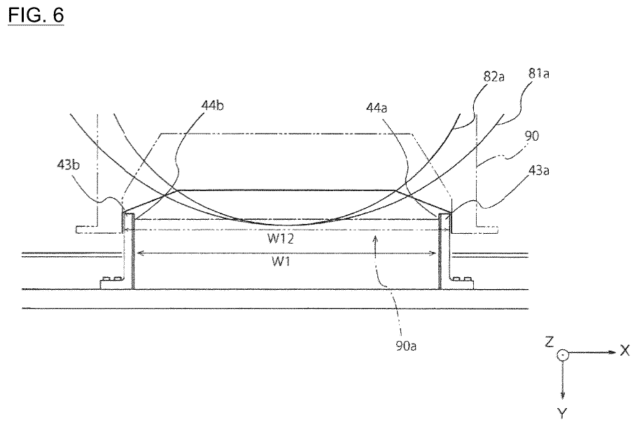

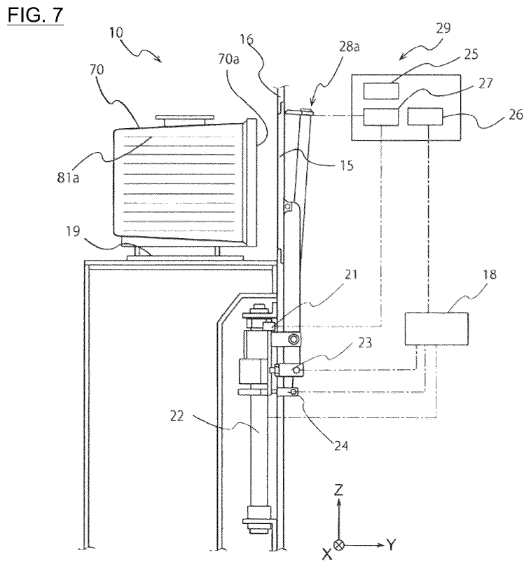

The present invention is described below with reference to embodiments illustrated in the drawing. FIG. 1 is a schematic perspective view of a load port apparatus 10 including a mapping apparatus 20 according to a first embodiment of the present disclosure. The mapping apparatus 20 according to the present embodiment is provided near a door 15 of the load port apparatus 10. The mapping apparatus 20 detects storing conditions of substrates or silicon wafers (e.g., first objects 81a (see FIG. 7) and second objects 82a (see FIG. 6)) as objects stored in a first container 70 (see FIG. 7) and a second container 90 (see FIG. 6) as containers installed on the load port apparatus 10.

The load port apparatus 10 is attached to an EFEM (not shown in the drawing) or the like for use in a semiconductor plant. The load port apparatus 10 functions as an interface for delivering objects (e.g., silicon wafers) stored in the first container 70, the second container 90, and the like to be transported therefrom to a predetermined semiconductor fabrication apparatus inside the semiconductor plant. Examples of the first container 70 and the second container 90 storing the first objects 81a and the second objects 82a include a FOUP, a FOSB, a SMIF, and an open cassette.

In the description of the load port apparatus 10 and the mapping apparatus 20 according to the first embodiment, a FOUP that can store the first objects 81a, which are 300 mm (12-inch) silicon wafers, exemplifies the first container 70; and an open cassette that can store the second objects 82a, which are 200 mm (8-inch) silicon wafers, exemplifies the second container 90. However, objects whose storing conditions are detected by the mapping apparatus 20 and their containers are not limited to those illustrated as examples of the first objects 81a, the second objects 82a, the first container 70, and the second container 90; and a combination of other objects and containers having different sizes or shapes may be used.

FIG. 7 is a diagram (partial sectional view) showing a first stage in a detection operation of the mapping apparatus 20 shown in FIG. 1. As shown in FIG. 7, the first container 70 can store the first objects 80a at predetermined intervals along a negative direction of the Z-axis, i.e., a first direction. At a side of the first container 70, the first container 70 has a main opening 70a, from which the first objects 80a are taken out.

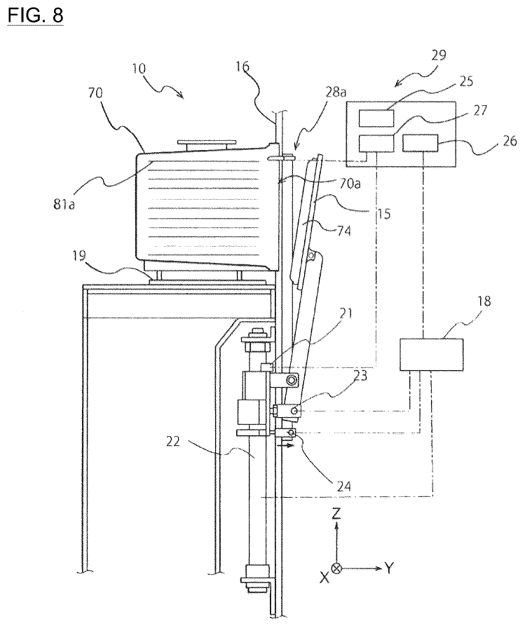

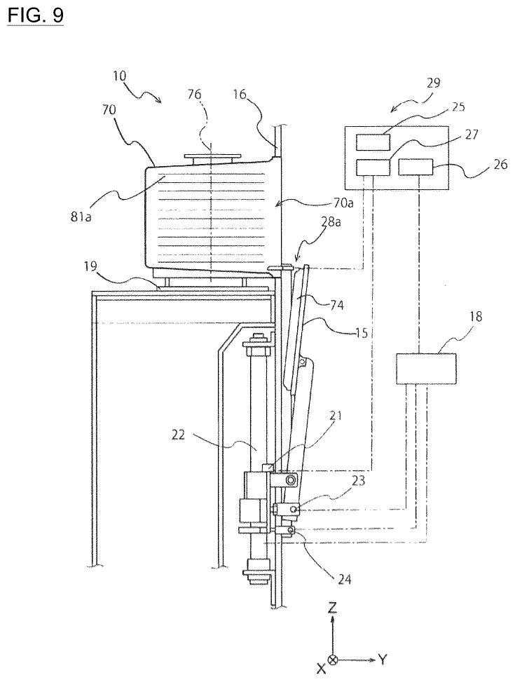

As shown in FIG. 1, the load port apparatus 10 includes, other than the mapping apparatus 20, an installation portion 19, on which to install the first container and the second container 90 storing the objects; a frame portion 16, which is attachable so as to block an opening of an EFEM; and the door 15, which opens and closes a lid 74 (see FIGS. 8 and 9) of the first container 70 and a frame opening of the frame portion 16. Note that the mapping apparatus 20 is not limited to the one provided for the load port apparatus 10; and the mapping apparatus 20 can be used for the first container 70, the second container 90, and other containers and slots storing the first objects 81a and the second objects 82a to detect storing conditions of the first objects 81a and the second objects 82a.

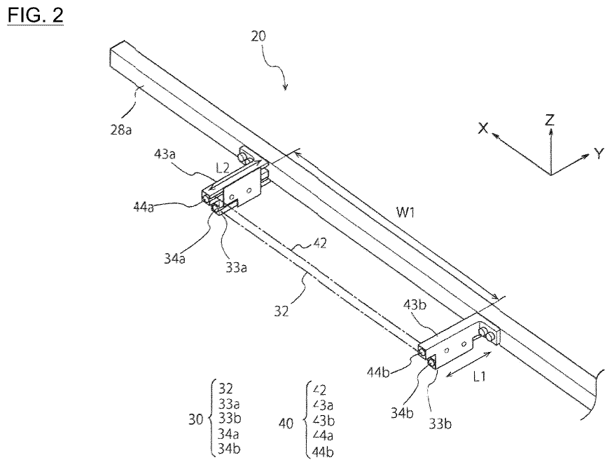

FIG. 2 is an enlarged perspective view of a main part of the mapping apparatus 20 shown in FIG. 1. As shown in FIG. 2, the mapping apparatus 20 includes a mapping frame 28 including a horizontal portion 28a; a first detecting unit 30; and a second detecting unit 40. The mapping apparatus 20 also includes, as elements that can optionally be selected whether or not to be included in the mapping apparatus 20, a third detecting unit 50 shown in FIG. 1; a mapping control 29 including a storage unit 25, a movement control unit 26, a computation unit 27, and the like shown in FIGS. 7 to 9; a first moving means 22; a second moving means 24; and the like.

In the description of the load port apparatus 10 and the mapping apparatus 20, as shown in FIG. 1 and FIGS. 7 to 9, a vertical direction is a Z-axis direction; a direction that is perpendicular to the Z-axis and in which the installation portion 19 approaches and draws away from the frame portion 16 is a Y-axis direction; and a direction perpendicular to the Z-axis and the Y-axis is an X-axis direction. In the mapping apparatus 20 according to the first embodiment, the first direction corresponds to the negative direction of the Z-axis; a second direction corresponds to a negative direction of the Y-axis; and a third direction corresponds to a negative direction of the X-axis. However, in mapping apparatuses according to other embodiments, the first to third directions may differ from those of the mapping apparatus 20 shown in FIG. 1 and the like.

As shown in FIG. 2, the first detecting unit 30 and the second detecting unit 40 of the mapping apparatus 20 are attached to the horizontal portion 28a, which extends in the third direction or the substantially horizontal direction, of the mapping frame 28. As shown in FIG. 1, in regard to the mapping frame 28 and the load port apparatus 10, the first detecting unit 30 and the second detecting unit 40 are disposed near the door 15 or the opening, which can be opened or closed by the door 15, of the frame portion 16.

As shown in FIGS. 1 and 7, in a state in which the opening of the frame portion 16 is closed with the door 15, the mapping frame 28 is disposed at a location away by a predetermined distance from the opening of the frame portion 16 in a positive direction of the Y-axis. By contrast, as shown in FIGS. 7 to 9, when storing conditions of the first objects 81a in the first container 70 are detected, the mapping frame 28 moves, from the state shown in FIGS. 1 and 7, in the second direction (negative direction of the Y-axis), which is substantially perpendicular to the first direction, and further in the first direction (negative direction of the Z-axis) (see FIGS. 8 and 9).

As shown in FIG. 2, the first detecting unit 30 is disposed at a level below (on the negative direction side of the Z-axis) the second detecting unit 40. The first detecting unit 30 includes a pair of first protrusions 33a and 33b protruding from the horizontal portion 28a of the mapping frame 28 in the second direction (negative direction of the Y-axis) in an amount of a first length L1 and first sensors 34a and 34b near respective extremities of the first protrusions 33a and 33b.

The first protrusions 33a and 33b of the first detecting unit 30 are disposed with a first distance W1 therebetween in the third direction (negative direction of the X-axis), which is perpendicular to the first direction and the second direction. Either the first sensor 34a or the first sensor 34b includes a light-emitting element, and the other includes a photodetector. The first detecting unit 30 detects the objects 81a and 82a intercepting a first detection axis 32 connecting the first sensors 34a and 34b. By this, the first detecting unit 30 detects the objects 81a and 82a protruding from storing locations in the first container 70 and the second container 90 for a length exceeding a predetermined length.

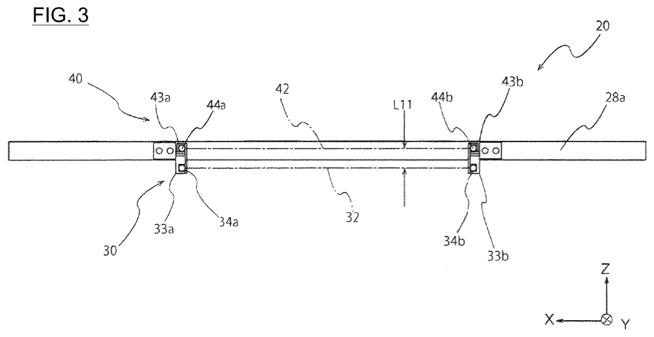

FIG. 3 is a front elevational view of the main part of the mapping apparatus 20 viewed along a direction opposite the second direction (viewed from the negative direction side to the positive direction side of the Y-axis). As shown in FIGS. 2 and 3, the second detecting unit 40 is disposed at a level above (on the positive direction side of the Z-axis) the first detecting unit 30. As shown in FIG. 2, the second detecting unit 40 includes a pair of second protrusions 43a and 43b protruding from the horizontal portion 28a of the mapping frame 28 in the second direction (negative direction of the Y-axis) in an amount of a second length L2 longer than the first length L1 and second sensors 44a and 44b near respective extremities of the second protrusions 43a and 43b.

The second protrusions 43a and 43b of the second detecting unit 40 are disposed at the same locations as the first protrusions 33a and 33b in the third direction (negative direction of the X-axis), which is perpendicular to the first direction and the second direction. Either the second sensor 44a or the second sensor 44b includes a light-emitting element, and the other includes a photodetector. The second detecting unit 40 detects locations and time of interception of a second detection axis 42 connecting the second sensors 44a and 44b by the objects 81a and 82a. By this, the second detecting unit 40 detects storing conditions of the objects 81a and 82a.

As shown in FIG. 3, the second detecting unit 40 is disposed at a location different from the location of the first detecting unit 30 by a predetermined distance L11 in the first direction (negative direction of the Z-axis). More specifically, as shown in FIG. 3, the second detection axis 42 of the second detecting unit 40 is disposed at a level above (in a direction opposite the first direction) the first detection axis 32 of the first detecting unit 30 in the first direction (negative direction of the Z-axis) by the predetermined distance L11.

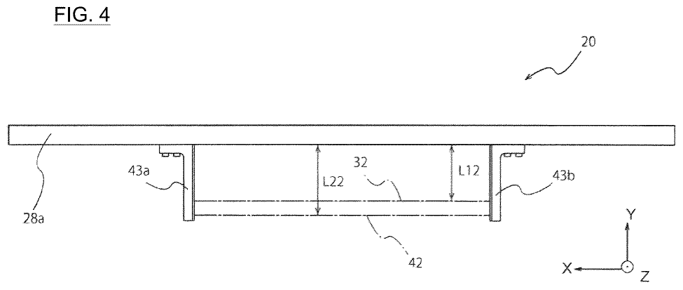

FIG. 4 is a plan view of the main part of the mapping apparatus 20 viewed along the first direction (from the positive direction side to the negative direction side of the Z-axis). As shown in FIG. 4, the first detection axis 32 of the first detecting unit 30 is away from the horizontal portion 28a of the mapping frame 28 by a length L12 in the second direction (negative direction of the Y-axis), and the second detection axis 42 of the second detecting unit 40 is away from the horizontal portion 28a of the mapping frame 28 by a length L22 in the second direction (negative direction of the Y-axis). Note that, the length L12, the length L22, and the difference between the length L12 and the length L22 shown in FIG. 4 may be slightly different from or may be the same as the first length L1, the second length L2, and the difference between the first length L1 and the second length L2 shown in FIG. 2.

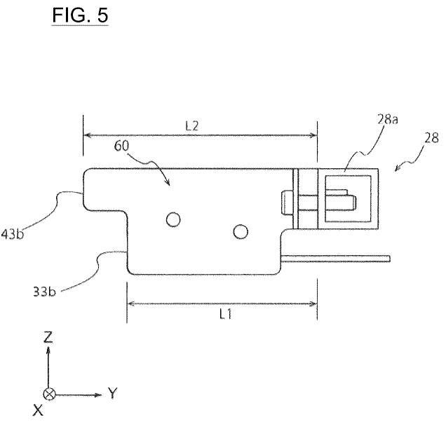

FIG. 5 is a schematic view illustrative of shapes of the first protrusion 33b and the second protrusion 43b of the mapping apparatus 20. As shown in FIG. 5, both the first protrusion 33b and the second protrusion 43b are portions of a sensor attachment unit 60 and constitute an integrated member. The sensor attachment unit 60 is fixed to the horizontal portion 28a of the mapping frame 28 using a bolt or the like. However, the shapes of the first protrusion 33b and the second protrusion 43b of the mapping apparatus 20 are not limited to the shapes shown in FIG. 5; and the first protrusion 33b and the second protrusion 43b may constitute separate members.

FIG. 6 is a schematic view illustrative of a state in which the mapping apparatus 20 detects the first objects 81a and the second objects 82a with different sizes. As shown in FIG. 6, the second container 90 storing the second objects 82a having a smaller size has an opening width W12 in the third direction (negative direction of the X-axis); and the opening width W12 is narrower than an opening width of the first container 70 storing the first objects 81a having a larger size. Thus, in the mapping apparatus 20 serving for the first objects 81a and the second objects 82a with different sizes, the first distance W1, which is the distance between the second protrusions 43a and 43b in the third direction, cannot be larger than the opening width W12 of the second container 90 in order for the second protrusions 43a and 43b to be able to enter the second container 90 having a narrow opening width. The mapping apparatus 20 has such a constraint.

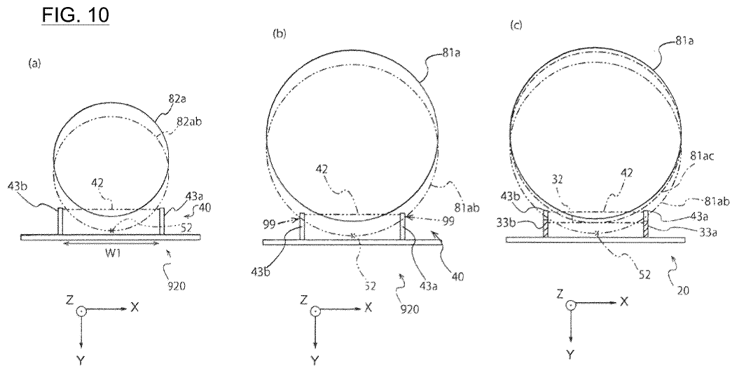

FIG. 10 is a schematic view comparing a mapping apparatus 920 according to a comparative example including only a second detecting unit 40 and the mapping apparatus 20 according to the embodiment. FIGS. 10(a) to 10(c) show positional relationships between the first detecting unit 30, the second detecting unit 40, the third detecting unit 50, and first objects 81a, 81ab, 81ac, a second object 82ab at the time of a detection operation. As shown in FIG. 10(a), provided that only the second object 82a having a smaller size is to be detected, the mapping apparatus 920, which does not include a first detecting unit and includes only the second detecting unit 40, has a wide range of tolerance in the protruding amount (amount of misalignment in the positive direction of the Y-axis) of an object. That is, provided that only the second object 82a is to be detected, second protrusions 43a and 43b of the mapping apparatus 920 according to the comparative example and the second object 82a do not come into contact with each other as long as the protruding amount is an amount not detected by a third detection axis 52 of a third detecting unit 50 disposed at a frame portion 16 (see FIG. 1) or the like (situation where the object is at a location closer to a normal location of the second object 82a shown in a solid line than to the location of the second object 82ab shown in a dashed-and-double-dotted line).

However, as shown in FIG. 10 (b), in a situation where the first object 81a having a larger size is to be detected with the mapping apparatus 920, the range of tolerance in the protruding amount of the object is narrower than that of the second object 82a having a smaller size. That is, in a situation where the first object 81a is to be detected, the second protrusions 43a and 43b of the mapping apparatus 920 according to the comparative example and the first object 81ab shown in a dashed-and-double-dotted line may come into contact with each other as shown by an arrow 99 even if the protruding amount is an amount not detected by the third detection axis 52 of the third detecting unit 50 disposed at the frame portion 16 (see FIG. 1) or the like. Also, if the mapping apparatus is exclusively for the first object 81a having a larger size, it is possible to provide support by increasing the distance between the second protrusions 43a and 43b in the third direction; however, it is difficult to increase the distance between the second protrusions 43a and 43b of the mapping apparatus supporting multiple sizes of objects.

In this respect, as shown in FIG. 3, the mapping apparatus 20 according to the first embodiment includes the first detecting unit 30 (diagonally hatched) including the first protrusions 33a and 33b having a shorter protruding length (first length L1) in the second direction (negative direction of the Y-axis) than the second detecting unit 40. Because the protruding length of the first detecting unit 30 in the second direction is shorter than that of the second detecting unit 40, the first protrusions 33a and 33b and the first object 81a do not come into contact with each other as shown in FIG. 10 (c), provided that the protruding amount is an amount not detected by the third detection axis 52 of the third detecting unit 50 (situation where the object is at a location closer to a normal location of the first object 81a shown in a solid line than to the location of the first object 81ab shown in a dashed-and-double-dotted line).

As shown in FIG. 10(c), the first detection axis 32 of the first detecting unit 30 is located between, in the second direction, the second detection axis 42 of the second detecting unit 40 and the third detection axis 52 of the third detecting unit 50. This enables the first detecting unit 30 to detect the first object 81a having a larger size, which is not detected by the third detecting unit 50 (the third detection axis 52) but is protruding in an amount that has a possibility of coming into contact with the second protrusions 43a and 43b (the first object located partway between the first objects 81ab and 81ac in FIG. 10(c)). When the first detecting unit 30 detects such first objects 81ab and 81ac, the mapping apparatus 20, for example, stops movement (lowering) of the mapping frame 28, enabling prevention of contact between the second protrusions 43a and 43b and the first object 81a.

The shortest distance from a container central axis 76 (see FIG. 1) parallel to the first direction of the first container 70 to the third detection axis 52 (see FIG. 10), which is a detection location of the third detecting unit 50, is longer than the shortest distances from the container central axis 76 to the first detection axis 32, which is a detection location of the first detecting unit 30, and to the second detection axis 42, which is a detection location of the second detecting unit 40. The third detecting unit 50 includes the third detection axis 52, which extends in the Z-axis direction near a center of the opening of the frame portion 16 as shown in, for example, FIG. 1.

Hereinafter, an example detection operation by the mapping apparatus 20 to detect storing conditions of the first objects 81a is described with reference to FIGS. 7 to 9. FIG. 7 shows a first stage in a detection operation by the mapping apparatus 20 to detect the first objects 81a. In the first stage shown in FIG. 7, the first container 70 storing the first objects 81a is installed on the installation portion 19 of the load port apparatus 10; however, the lid 74 of the first container 70 is closed, and the first container 70 is not connected to the frame portion 16 of the load port apparatus 10. Also, in the state shown in FIG. 7, the mapping apparatus 20 itself has not started the detection operation.

FIG. 8 shows a second stage in the detection operation by the mapping apparatus 20 to detect the substrates 80. In the second stage shown in FIG. 8, the first container 70 installed on the installation portion 19 is connected to the frame portion 16, and the lid 74 of the first container 70 is opened by the door 15. The door 15 engaged with the frame portion 16 as shown in FIG. 7 engages with the lid 74 of the first container 70; and then, the door 15 is drawn in the positive direction of the Y-axis by a third moving means 23 as shown in FIG. 8 to open the lid 74 of the first container 70.

Further, the second moving means 24 of the mapping apparatus 20 moves the horizontal portion 28a of the mapping frame 28 in the second direction (negative direction of the Y-axis) to insert at least a part of the first detecting unit 30 and at least a part of the second detecting unit 40 fixed to the horizontal portion 28a of the mapping frame 28 into the first container 70. This makes the second detection axis 42 of the second detecting unit 40 be disposed at a level above the first objects 81a stored in the first container 70, as shown in FIG. 6.

The second moving means 24 turns the mapping frame 28 or parallelly moves the mapping frame 28 in the Y-axis direction to move the horizontal portion 28a of the mapping frame 28 in the Y-axis direction. Note that the second moving means 24 can move the horizontal portion 28a of the mapping frame 28 in the second direction (negative direction of the Y-axis) independently from opening and closing of the door 15 by the third moving means 23.

FIG. 9 shows a third stage in the detection operation by the mapping apparatus 20 to detect the first objects 81a. In the third stage shown in FIG. 9, the first moving means 22 moves the mapping frame 28 in the first direction (negative direction of the Z-axis) to move the first detecting unit 30 and the second detecting unit 40, which are disposed at a level above that of the first object 81a stored in the highest slot in FIG. 8, to a level below that of the first object 81a stored in the lowest slot as shown in FIG. 9.

That is, the first moving means 22 moves the first detecting unit 30 and the second detecting unit 40 along the first direction, which is the arrangement direction, so that the second detection axis 42 intersects the first objects 81a subject to detection one by one in sequence. At this time, the second sensors 44a and 44b of the second detecting unit 40 output detection signals, which changes in response to interception by the first objects 81a, to the computation unit 27 of the mapping apparatus 20 shown in FIGS. 7 to 9. The mapping apparatus 20 also includes a sensor location detecting unit 21, which detects the location of the second detecting unit 40 in the Z-axis direction for output to the computation unit 27.

Using the detection signals from the second detecting unit 40, the location information from the sensor location detecting unit 21, and the like, the computation unit 27 detects the storing conditions of the first objects 81a stored in the first container 70. As shown in FIGS. 7 to 9, the mapping apparatus 20 includes the mapping control 29 including the computation unit 27, the storage unit 25, the movement control unit 26, and the like. For example, a microcontroller, a memory, and the like constitute the mapping control 29.

The storage unit 25 stores a second detection result, which is a result of detection of the first objects 81a by the second detecting unit 40. To the movement control unit 26, a first detection result, which is a result of detection of the first objects 81a stored in the first container 70 by the first detecting unit 30, is input. Further, when the first detection result indicates detection of the first objects 81a by the first sensors 34a and 34b, the movement control unit 26 can stop movement of the mapping frame 28 before the mapping frame 28 is moved downwards by the predetermined distance L11 (see FIG. 3) from the point of detection of the first objects 81a by the first sensors 34a and 34b. Note that moving and stopping operations of the mapping frame 28 by the movement control unit 26 may be performed directly from the mapping control 29 or may be performed from the mapping control 29 via a load port control 18, which controls the entire load port apparatus 10.

Detection of storing conditions of the second objects 82a (see FIG. 6) by the mapping apparatus 20 can also be performed similarly to the above-mentioned second objects 82a. However, as shown in FIG. 10(a), when the second objects 82a, which may possibly collide with the second protrusions 43a and 43b, can entirely be detected by the third detecting unit 50, detection may be performed without operation of the first detecting unit 30. Also, for example, when the second container 90 storing the second objects 82a is an open cassette, it may be that the mapping apparatus 20 or the load port apparatus 10 can perform an operation of rotating the second container 90 by 90 degrees on the installation portion 19 and changing the arrangement direction of the second objects 82a from the Y-axis direction to the Z-axis direction.

The mapping apparatus 20 according to the present embodiment includes the first detecting unit 30 and the second detecting unit 40, which are disposed at the respective locations different by the predetermined distance L11 in the first direction (negative direction of the Z-axis), which is the direction in which the objects overlap; and the protruding length (second length L2) of the second protrusions 43a and 43b is longer than the protruding length (first length L1) of the first protrusions 33a and 33b. Because the protruding length of the first detecting unit 30 is short, it can detect the objects 81a and 82a, which may collide with the second detecting unit 40 having the longer protruding length, while avoiding contact with the objects 81a and 82a protruding from storing locations of their containers; and appropriate operation of the mapping frame 28 and the like can prevent a collision between the objects 81a and 82a and the second detecting unit 40. By locating the first protrusions 33a and 33b and the second protrusions 43a and 43b at the same locations in the third direction (negative direction of the X-axis), the second protrusions 43a and 43b can have a large distance (W1) therebetween in the third direction, making the most of the opening width W12 (see FIG. 6) of the second container 90 for the second objects 82a having a smaller size; and the range of tolerance in the protruding amount (amount of misalignment in the positive direction of the Y-axis) of the first objects 81a can be widened, though the mapping apparatus 20 is for both the first objects 81a and the second objects 82a.

### Second Embodiment

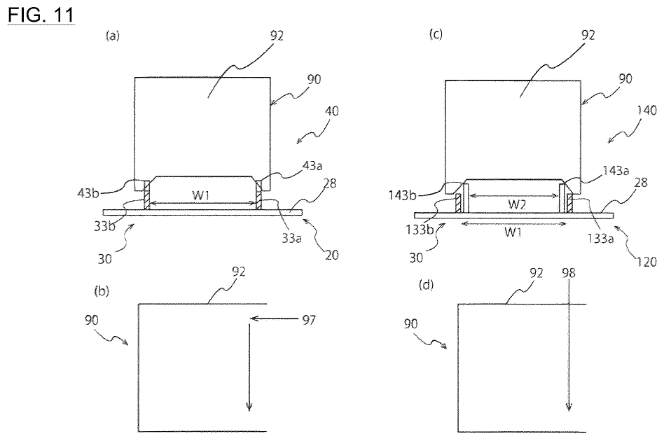

FIG. 11 is a schematic view comparing the mapping apparatus 20 according to the first embodiment and a mapping apparatus 120 according to a second embodiment. FIG. 11 (a) shows shapes of the first protrusions 33a and 33b and the second protrusions 43a and 43b of the mapping apparatus 20 according to the first embodiment and a first direction upper surface 92 of the second container 90 overlapping. As shown in FIG. 11(a), in the mapping apparatus 20 according to the first embodiment, the distance between the second protrusions 43a and 43b in the third direction substantially corresponds to the first distance W1 between the first protrusions 33a and 33b in the third direction. In this situation, the distance between the second protrusions 43a and 43b in the third direction can be increased, in which case the extremities of the second protrusions 43a and 43b and the first direction upper surface 92 of the second container 90 partly overlap when viewed from the Z-axis direction.

Thus, as shown by an arrow 97 in FIG. 11(b), in the mapping apparatus 20, when the first detecting unit 30 and the second detecting unit 40 are inserted into the second container 90, insertion needs to be performed after the levels of the first detecting unit 30 and the second detecting unit 40 are adapted according to the level of the first direction upper surface 92 of the second container 90. By contrast, FIG. 11(c) shows shapes of first protrusions 133a and 133b and second protrusions 143a and 143b of the mapping apparatus 120 according to the second embodiment and the first direction upper surface 92 of the second container 90 overlapping.

As shown in FIG. 11(c), the second protrusions 143a and 143b of a second detecting unit 140 of the mapping apparatus 120 according to the second embodiment are disposed with a second distance W2 narrower than the first distance W1 therebetween in the third direction. In the mapping apparatus 120, when viewed from the Z-axis direction, extremities of the second protrusions 143a and 143b and the first direction upper surface 92 of the second container 90 do not overlap, unlike in FIG. 11(a).

Thus, as shown by an arrow 98 in FIG. 11(d), when a first detecting unit 30 and the second detecting unit 40 of the mapping apparatus 120 are inserted into the second container 90, the first detecting unit 30 and the second detecting unit 40 can be lowered along the Z-axis direction to perform insertion, without adaptation of their levels according to the level of the first direction upper surface 92 of the second container 90. With this mapping apparatus 120, for example, it is possible to commonize movement of a mapping frame 28 at the time of detection for the first objects 81a stored in the first container 70 and for the second objects 82a stored in the second container 90.

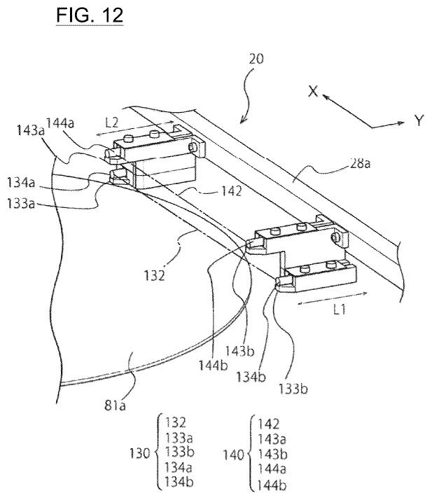

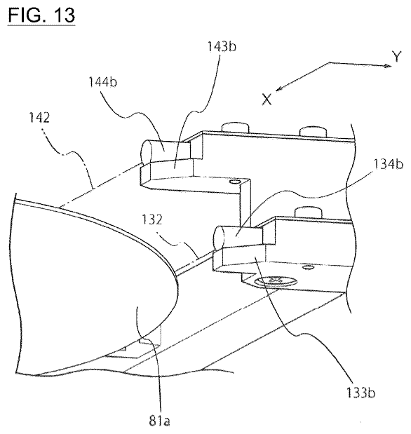

FIG. 12 is a schematic perspective view of a main part of the mapping apparatus 120 according to the second embodiment. FIG. 13 is a partial enlarged view of the first protrusion 133b, a first sensor 134b, the second protrusion 143b, and a second sensor 144b of the mapping apparatus 120. As shown in FIGS. 12 and 13, the mapping apparatus 120 also includes the first detecting unit 130 and the second detecting unit 140 similarly to the mapping apparatus 20 shown in FIG. 2.

As shown in FIG. 12, the first detecting unit 130 includes the pair of first protrusions 133a and 133b protruding from a horizontal portion 28a of the mapping frame 28 in the second direction (negative direction of the Y-axis) in an amount of a first length L1 and first sensors 134a and 134b near respective extremities of the first protrusions 133a and 133b. The first protrusions 133a and 133b of the first detecting unit 130 are disposed with a first distance W1 therebetween in the third direction (negative direction of the X-axis), which is perpendicular to the first direction and the second direction (see FIG. 11(c)).

Either the first sensor 134a or the first sensor 134b includes a light-emitting element, and the other includes a photodetector. The first detecting unit 130 detects the objects 81a and 82a intercepting a first detection axis 132 connecting the first sensors 134a and 134b. By this, the first detecting unit 130 detects the objects 81a and 82a protruding from storing locations in the first container 70 and the second container 90 for a length exceeding a predetermined length.

As shown in FIG. 12, the second detecting unit 140 is disposed at a level above (on the positive direction side of the Z-axis) the first detecting unit 130. As shown in FIGS. 12 and 13, the second detecting unit 140 includes the pair of second protrusions 143a and 143b protruding from the horizontal portion 28a of the mapping frame 28 in the second direction (negative direction of the Y-axis) in an amount of a second length L2 longer than the first length L1 and second sensors 144a and 144b near respective extremities of the second protrusions 143a and 143b. The second protrusions 143a and 143b of the second detecting unit 140 are disposed with the second distance W2 narrower than the first distance W1 therebetween in the third direction (see FIG. 11(c)). Also, similarly to the mapping apparatus 20 shown in FIG. 3, the second detecting unit 140 is disposed at a location different from the location of the first detecting unit 30 by a predetermined distance in the first direction (negative direction of the Z-axis). The second detecting unit 140 detects locations and time of interception of a second detection axis 142 connecting the second sensors 144a and 144b by the objects 81a and 82a. By this, the second detecting unit 140 detects storing conditions of the objects 81a and 82a.

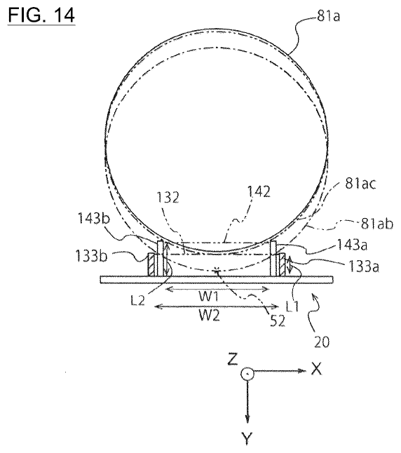

FIG. 14 shows a positional relationship between the first detecting unit 130, the second detecting unit 140, and first objects 81a, 81ab, 81ac at the time of a detection operation. Similarly to the first detecting unit 30 shown in FIG. 10, the first detecting unit 130 shown in FIG. 14 can detect the first object 81a having a larger size, which is not detected by a third detection axis 52 of a third detecting unit but is protruding in an amount that has a possibility of coming into contact with the second protrusions 143a and 143b (the first object located partway between the first objects 81ab and 81ac in FIG. 14).

However, in the mapping apparatus 120 shown in FIG. 14, the second distance W2 of the second detecting unit 140 in the third direction is narrower than the distance (first distance W1) of the second detecting unit 40 in the third direction of the mapping apparatus 20 shown in FIG. 10(c). Thus, in the mapping apparatus 120, the range of tolerance in the protruding amount of the first objects, which do not come in contact with the second protrusions 143a and 143b of the second detecting unit 140, is narrower than that of the mapping apparatus 20; and the distance between the first detection axis 132 and the second detection axis 142 in the Y-axis direction needs to be narrower.

Except that the second protrusions 143a and 143b of the second detecting unit 140 are disposed with the second distance W2 narrower than the first distance W1 therebetween, the mapping apparatus 120 according to the second embodiment is similar to the mapping apparatus 20; and what is common to the mapping apparatuses 120 and 20 exhibits similar effects brought by the mapping apparatus 20.

Hereinabove, the present invention has been described using the embodiments; however, needless to say, the present invention is not limited to the embodiments described above and includes other embodiments and modified examples. For example, while the first direction is a downward direction and the first detecting units 30 and 130 of the mapping apparatuses 20 and 120 are disposed at a level below the second detecting units 40 and 140 by the predetermined distance L11, it may be that, conversely, the first direction is an upward direction and the first detecting unit is disposed at a level above the second detecting unit by the predetermined distance. In a situation where the first direction is a downward direction, the mapping frame 28 of the mapping apparatus 20 or 120 moves downwards to detect the objects 81a and 82a. By contrast, in a situation where the first direction is an upward direction, the mapping frame of the mapping apparatus moves upwards to detect the objects.

Also, the shape of the sensor attachment unit 60 or the mapping frame 28 of the mapping apparatus 20 or 120 is not limited to the shape shown in FIG. 5 or FIG. 13 and can be appropriately changed according to, for example, the shapes of the first and second sensors 33a, 33b, 133a, 133b, 34a, 34b, 134a, and 134b. Also, while the first detection axes 32 and 132 of the first detecting units 30 and 130 and the second detection axes 42 and 142 of the second detecting units 40 and 140 may be parallel to the third direction, the detection axes may be inclined relative to the third direction or the horizontal direction.

The combination of the first sensors 33a, 33b, 133a, and 133b and the second sensors 43a, 43b, 143a, and 143b is not limited to a combination of a light-emitting element and a photodetector and may be a combination of a light-emitting element/a photodetector and a reflective element; a combination of a generator of electromagnetic waves other than light and a detecting unit; or other combinations.

### REFERENCE NUMERALS

10 . . . load port apparatus
15 . . . door
16 . . . frame portion
18 . . . load port control
19 . . . installation portion
20, 120 . . . mapping apparatus
21 . . . sensor location detecting unit
22 . . . first moving means
23 . . . third moving means
24 . . . second moving means
25 . . . storage unit
26 . . . movement control unit
27 . . . computation unit
28 . . . mapping frame
28a . . . horizontal portion
29 . . . mapping control
30, 130 . . . first detecting unit
32, 132 . . . first detection axis
33a, 33b, 133a, 133b . . . first protrusion
34a, 34b, 134a, 134b . . . first sensor
L1 . . . first length
W1 . . . first distance
L12, L11, L22 . . . length
40, 140 . . . second detecting unit
42, 142 . . . second detection axis
43a, 43b, 143a, 143b . . . second protrusion
44a, 44b, 144a, 144b . . . second sensor
L2 . . . second length
R2 . . . second detection result
50 . . . third detecting unit
52 . . . third detection axis
70 . . . first container
70a . . . main opening
74 . . . lid
76 . . . container central axis
81a . . . first object
82a . . . second object
90 . . . second container
92 . . . first direction upper surface
W12 . . . opening width
97, 98, 99 . . . arrow

1-12. (canceled)

13. A mapping apparatus for detecting a storing condition of objects in a container capable of storing the objects at predetermined intervals along a first direction, comprising:
a mapping frame configured to move in the first direction and a second direction substantially perpendicular to the first direction;
a first detecting unit comprising
a pair of first protrusions protruding from the mapping frame in the second direction in an amount of a first length, the first protrusions being disposed with a first distance therebetween in a third direction substantially perpendicular to the first direction and the second direction, and
first sensors near respective extremities of the first protrusions; and
a second detecting unit comprising
a pair of second protrusions protruding from the mapping frame in the second direction in an amount of a second length longer than the first length, the second protrusions being disposed at locations same as those of the first protrusions in the third direction, and
second sensors near respective extremities of the second protrusions,
the second detecting unit being disposed at a location different from that of the first detecting unit by a predetermined distance in the first direction.

14. The mapping apparatus according to claim 13, wherein either the first direction is a downward direction, and
the first detecting unit is disposed at a level below the second detecting unit by the predetermined distance; or
the first direction is an upward direction, and
the first detecting unit is disposed at a level above the second detecting unit by the predetermined distance.

15. The mapping apparatus according to claim 13, comprising a storage unit configured to store a second detection result, wherein the second detection result comprises a result of detection of the objects by the second detecting unit.

16. The mapping apparatus according to claim 13, comprising a movement control unit configured to stop movement of the mapping frame before the mapping frame is moved by the predetermined distance from a point of detection of the objects by the first sensors, provided that a first detection result is input to the movement control unit and indicates the detection of the objects by the first sensors, wherein the first detection result comprises a result of detection of the objects by the first detecting unit.

17. The mapping apparatus according to claim 13, comprising a third detecting unit, wherein a shortest distance from a container central axis parallel to the first direction of the container to a detection location of the third detecting unit is longer than shortest distances from the container central axis to detection locations of the first detecting unit and the second detecting unit.

18. A load port apparatus comprising:
the mapping apparatus according to claim 13;
an installation portion configured to have the container installed thereon; and
a door configured to open or close a lid of the container.

19. A mapping apparatus for detecting a storing condition of objects in a container capable of storing the objects at predetermined intervals along a first direction, comprising:
a mapping frame movable in the first direction and a second direction substantially perpendicular to the first direction;
a first detecting unit comprising
a pair of first protrusions protruding from the mapping frame in the second direction in an amount of a first length, the first protrusions being disposed with a first distance therebetween in a third direction substantially perpendicular to the first direction and the second direction, and
first sensors near respective extremities of the first protrusions; and
a second detecting unit comprising
a pair of second protrusions protruding from the mapping frame in the second direction in an amount of a second length longer than the first length, the second protrusions being disposed with a second distance narrower than the first distance therebetween in the third direction, and
second sensors near respective extremities of the second protrusions,
the second detecting unit being disposed at a location different from that of the first detecting unit by a predetermined distance in the first direction.

20. The mapping apparatus according to claim 19, wherein either the first direction is a downward direction, and
the first detecting unit is disposed at a level below the second detecting unit by the predetermined distance; or
the first direction is an upward direction, and
the first detecting unit is disposed at a level above the second detecting unit by the predetermined distance.

21. The mapping apparatus according to claim 19, comprising a storage unit configured to store a second detection result, wherein the second detection result comprises a result of detection of the objects by the second detecting unit.

22. The mapping apparatus according to claim 19, comprising a movement control unit configured to stop movement of the mapping frame before the mapping frame is moved by the predetermined distance from a point of detection of the objects by the first sensors, provided that a first detection result is input to the movement control unit and indicates the detection of the objects by the first sensors, wherein the first detection result comprises a result of detection of the objects by the first detecting unit.

23. The mapping apparatus according to claim 19, comprising a third detecting unit, wherein a shortest distance from a container central axis parallel to the first direction of the container to a detection location of the third detecting unit is longer than shortest distances from the container central axis to detection locations of the first detecting unit and the second detecting unit.

24. A load port apparatus comprising:
the mapping apparatus according to claim 19;
an installation portion configured to have the container installed thereon; and
a door configured to open or close a lid of the container.
